(19) United States
(12) Patent Application Publication
(10) Pub. No.: US 2026/0251989 A1
(43) Pub. Date: Aug. 27, 2026

(54) SEMICONDUCTOR DEVICE HAVING ALIGNMENT MARK

(71) Applicant: Micron Technology, Inc., Boise, ID (US)

(72) Inventors: Hiroshi Toyama, Hiroshima (JP); Toshio Fukai, Hiroshima (JP); Kazushi Suzuki, Hiroshima-city (JP)

(73) Assignee: Micron Technology, Inc., Boise, ID (US)

(21) Appl. No.: 19/537,336

(22) Filed: Feb. 11, 2026

Related U.S. Application Data
(60) Provisional application No. 63/763,800, filed on Feb. 26, 2025.

(51) Int. Cl. G03F 9/00; G03F 7/00; H10W 90/00

(52) U.S. Cl. CPC G03F 9/7076; G03F 7/70633; G03F 9/7084; H10W 90/754

(57) ABSTRACT

An example apparatus includes: first and second chip regions arranged in a first direction, each of the first and second chip regions including a plurality of circuit elements; a scribe region arranged between the first and second chip regions in the first direction and extending in a second direction perpendicular to the first direction; and a rectangle-shaped landing pattern having a notch at a substantially center portion in the first direction of each of two sides opposite to each other in the second direction.

### CROSS-REFERENCE TO RELATED APPLICATIONS

This application claims the filing benefit of U.S. Provisional Application No. 63/763,800, filed February 26, 2025. This application is incorporated by reference herein in its entirety and for all purposes.

### BACKGROUND

Semiconductor devices are manufactured through a plurality of processes including an exposure process. In the exposure process, positioning is performed using an alignment mark formed using a part of a wiring layer. It is a normal procedure that such an alignment mark is located on a scribe region that is positioned at an end part of a chip in order to secure an effective area in a device region. The alignment mark located on the scribe region is positioned on a dicing line, so that it is cut at the time of dicing a semiconductor wafer.

### BRIEF DESCRIPTION OF THE DRAWINGS

FIG. 1 is a schematic plan view showing a configuration of a semiconductor wafer;

FIG. 2 is a schematic enlarged view of an area A shown in FIG. 1;

FIGS. 3A and 3B are schematic cross sections of an alignment mark;

FIG. 4A is a schematic plan view showing a state where a plurality of reformed regions are formed along a dicing line;

FIG. 4B is a schematic plan view showing a state where a semiconductor wafer is cut along the dicing line;

FIG. 5 is a schematic partial perspective view showing a side surface of a diced semiconductor chip;

FIG. 6 is a schematic partial cross section showing a cross section of a diced semiconductor chip;

FIGS. 7A to 7C are schematic diagrams for explaining variations of notches; and

FIGS. 8A and 8B are schematic diagrams for explaining variations of a pattern recognizing part of the alignment mark.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

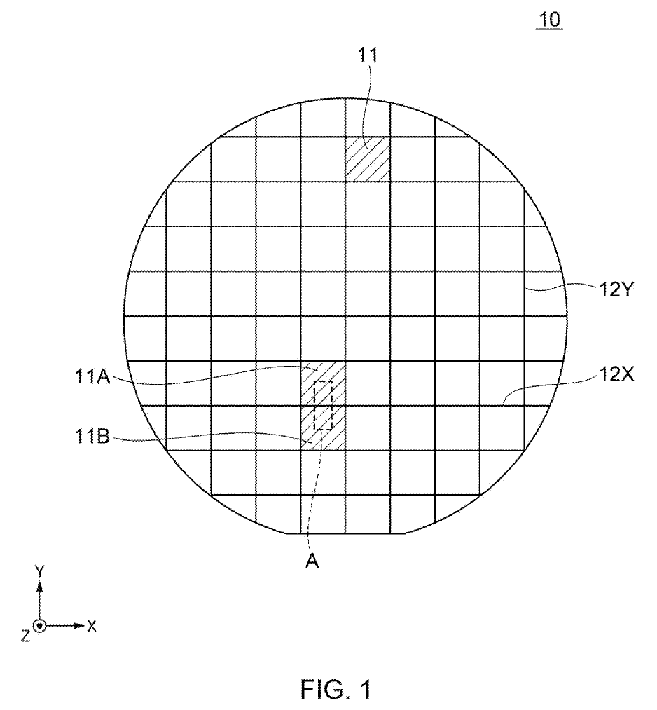

FIG. 1 is a schematic plan view showing a configuration of a semiconductor wafer 10. As shown in FIG. 1, the semiconductor wafer 10 is a circular plate with a Z direction as the thickness direction and includes a plurality of chip regions 11. The plurality of chip regions 11 are partitioned by a plurality of scribe regions 12X extending in an X direction and a plurality of scribe regions 12Y extending in a Y direction. In some examples, the X direction is perpendicular to the Y direction. The chip regions 11 are regions in which a plurality of circuit elements are integrated. The scribe regions 12X and 12Y are regions to be cut when the chip regions 11 are diced. Any circuit element operated in actual use is not located on the scribe regions 12X and 12Y.

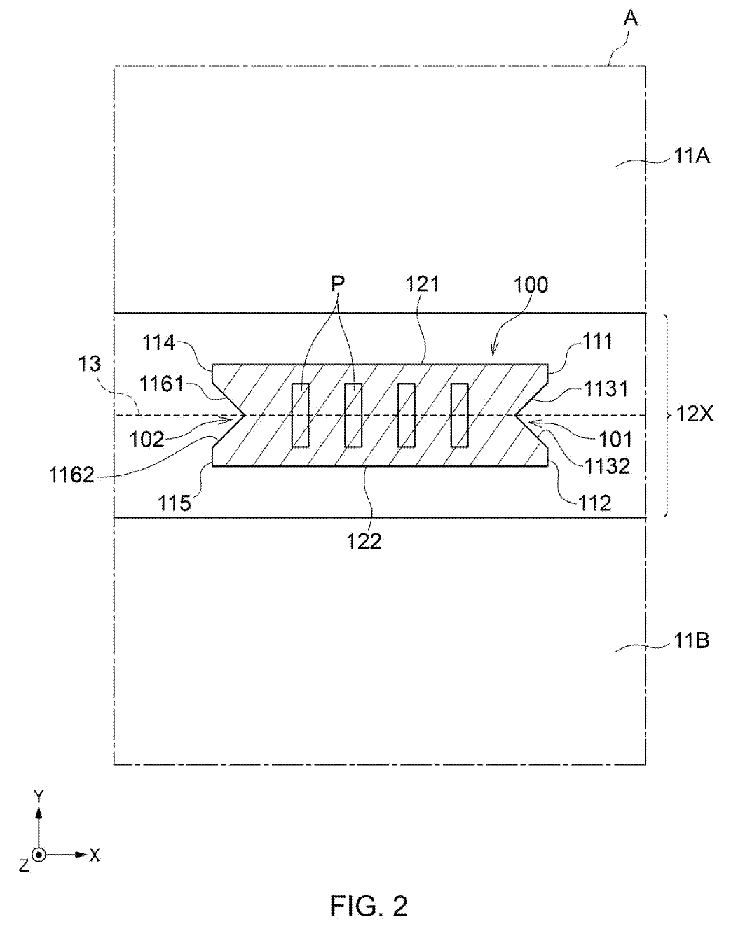

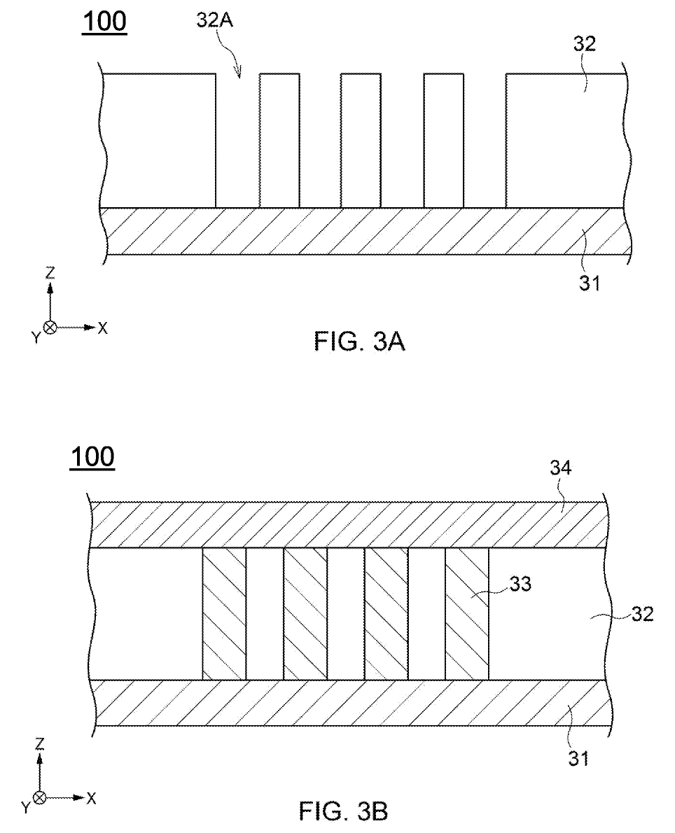

FIG. 2 is a schematic enlarged view of an area A shown in FIG. 1. The area A shown in FIG. 1 includes two chip regions 11A and 11B adjacent to each other in the Y direction and a scribe region 12X positioned between the chip regions 11A and 11B. The scribe region 12X extends in the X direction. As shown in FIG. 2, an alignment mark 100 is located on the scribe region 12X. A pattern recognizing part P included in the alignment mark 100 is used for positioning in an exposure process. The alignment mark 100 may be constituted of a landing pattern made of metal or the like and vias provided in an interlayer insulating film covering the landing pattern or via conductors embedded in vias. For example, in the example shown in FIG. 3A, the alignment mark 100 is constituted of a landing pattern 31, an interlayer insulating film 32 covering the landing pattern 31, and a plurality of vias 32A provided in the interlayer insulating film 32 so as to overlap the landing pattern 31. At this time point, the plurality of vias 32A provided in the interlayer insulating film 32 function as the pattern recognizing part P of the alignment mark 100. As shown in FIG. 3B, the vias 32A are filled with via conductors 33 in a subsequent process. At this time point, a plurality of via conductors 33 provided in the interlayer insulating film 32 function as the pattern recognizing part P of the alignment mark 100. In a further subsequent process, another landing pattern 34 is formed on the interlayer insulating film 32. In this manner, in each process, the alignment mark 100 has its characteristic shape portion used as a pattern recognizing part P for alignment.

As shown in FIG. 2, the landing pattern constituting the alignment mark 100 has a substantially rectangle shape in plan view as viewed from the Z direction, and a notch 101 and a notch 102 are respectively provided on end parts positioned at both sides of the landing pattern in the X direction. The notches 101 and 102 are notch-shaped parts of the alignment mark 100 and the length of the alignment mark 100 in the X direction is shorter at portions where the notches 101 and 102 are provided. For example, the length of a line connecting the tip of the notch 101 and the tip of the notch 102 in the X direction is shorter than the length in the X direction of end parts 121 and 122 extending in the X direction of the alignment mark 100. An end part positioned on a +X direction side of the alignment mark 100 includes sections 111 and 112 extending in the Y direction and sections 1131 and 1132 positioned between the sections 111 and 112 and extending obliquely with respect to the Y direction. The sections 1131 and 1132 are portions positioned on a -X direction side with respect to the sections 111 and 112 and a region surrounded by an imaginary line in the Y direction linearly connecting the section 111 and the section 112 and the sections 1131 and 1132 constitutes the notch 101. An end part positioned on the -X direction side of the alignment mark 100 includes sections 114 and 115 extending in the Y direction and sections 1161 and 1162 positioned between the sections 114 and 115 and extending obliquely with respect to the Y direction. The sections 1161 and 1162 are portions positioned on the +X direction side with respect to the sections 114 and 115 and a region surrounded by an imaginary line in the Y direction linearly connecting the section 114 and the section 115 and the sections 1161 and 1162 constitutes the notch 102. In the example shown in FIG. 2, the shape of the notches 101 and 102 is triangular and the tip thereof is sharp. The width of the notches 101 and 102 in the Y direction may exceed half the width of the alignment mark 100 in the Y direction. The length of the notches 101 and 102 in the X direction may exceed the width of the notches 101 and 102 in the Y direction.

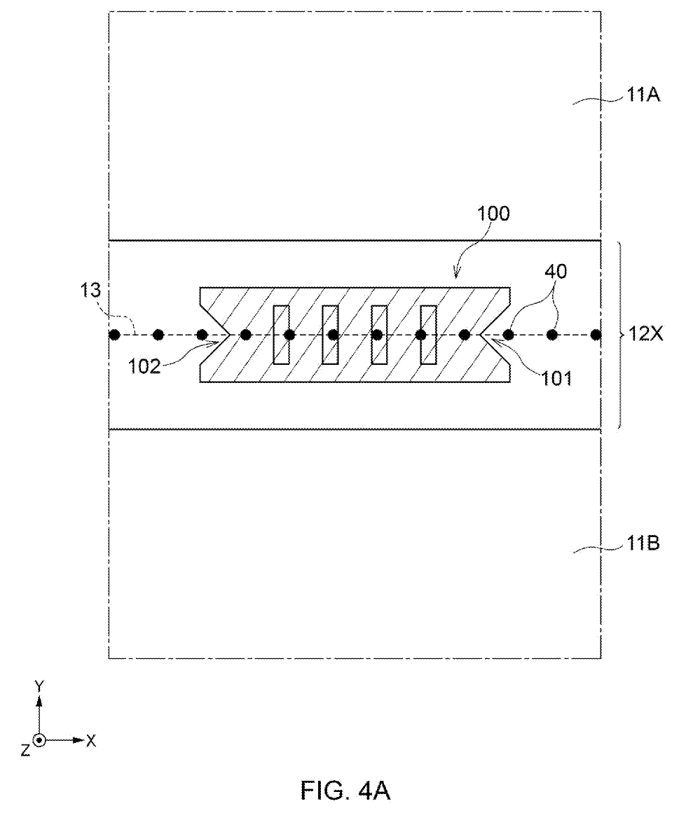

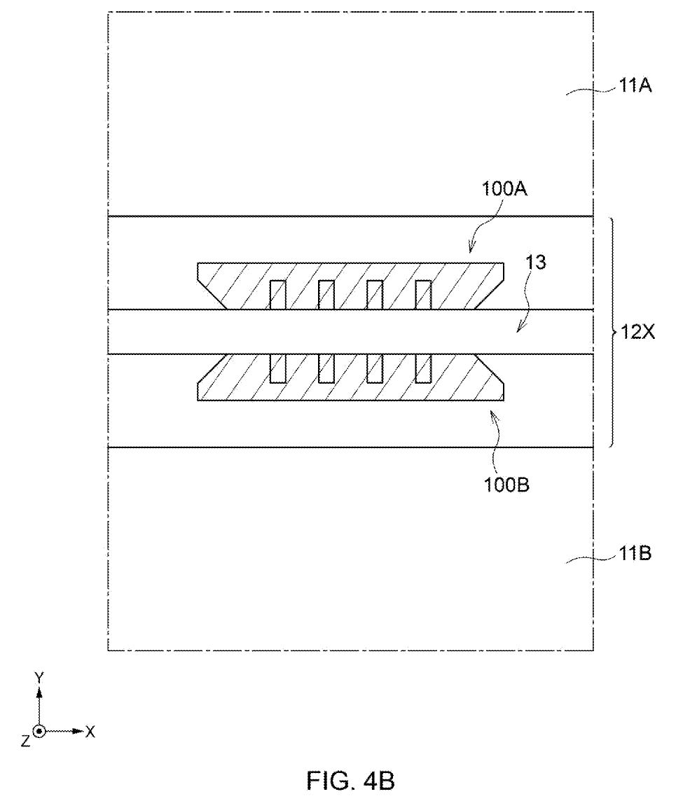

When the semiconductor wafer 10 is diced into a plurality of chip regions 11, the semiconductor wafer 10 is cut along a dicing line defined within the scribe regions 12X and 12Y. For example, a dicing line 13 shown in FIG. 2 is defined in the scribe region 12X and the semiconductor wafer 10 is cut along the dicing line 13. As shown in FIG. 2, the dicing line 13 is defined as it passes the respective tips of the notches 101 and 102. When the semiconductor wafer 10 is actually diced, as shown in FIG. 4A, by irradiating the semiconductor wafer 10 with a laser beam intermittently along the dicing line 13, a plurality of reformed regions 40 along the dicing line 13 are formed inside the semiconductor wafer 10. Thereafter, as a stretchable tape is widened in all directions equally in a state where the semiconductor wafer 10 is adhered to the tape, as shown in FIG. 4B, the semiconductor wafer 10 is cut along the dicing line 13 with the reformed regions 40 functioning as points of origin. The alignment mark 100 is separated into a remaining part 100A that remains on the chip region 11A side and a remaining part 100B that remains on the chip region 11B side. At this time, as the cutting position of the semiconductor wafer 10 is positioned near the respective tips of the notches 101 and 102, when the semiconductor wafer 10 is cut along the dicing line 13, the alignment mark 100 is guided by the notches 101 and 102 and properly cut into the remaining parts 100A and 100B. That is, if the notches 101 and 102 are not present, there is no point of origin in terms of cutting on the alignment mark 100. Therefore, for example, a part or all of the portion originally supposed to remain on the chip region 11A side as the remaining part 100A may be drawn into the chip region 11B side. In this case, a part of the alignment mark 100 drawn into the chip region 11B side is in a state of projecting from a side surface of a chip, thereby causing poor appearance. On the other hand, in the present embodiment, since the alignment mark 100 is cut properly along the dicing line 13, such poor appearance hardly occurs.

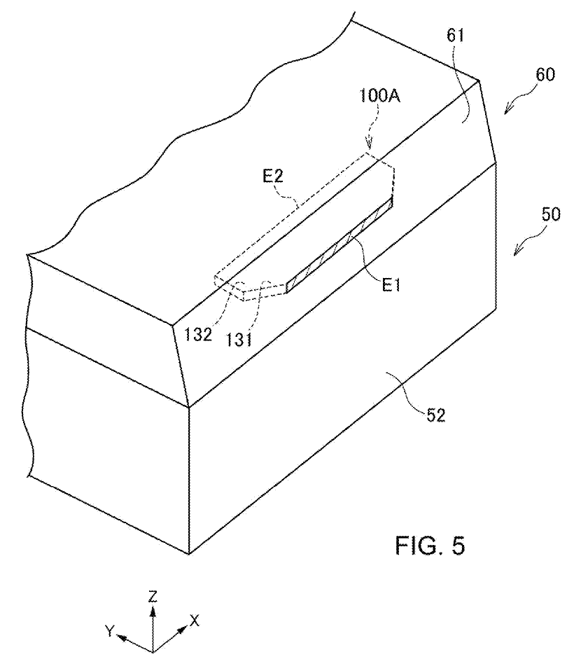

FIG. 5 is a schematic partial perspective view showing a side surface of a diced semiconductor chip. As shown in FIG. 5, the semiconductor chip includes a semiconductor substrate 50 made of silicon or the like and a circuit layer 60 laminated on the semiconductor substrate 50. A side surface 52 of the semiconductor substrate 50 and a side surface 61 of the circuit layer 60 constitutes substantially the same plane. Further, a part of the remaining part 100A of the alignment mark 100 is exposed from the side surface 61 of the circuit layer 60. Here, when an edge of the remaining part 100A exposed from the side surface 61 of the circuit layer 60 is denoted as E1 and another edge of the remaining part 100A positioned on the opposite side of the edge E1 and extending in parallel to the edge E1 is denoted as E2, the length of the edge E1 in the X direction is shorter than the length of the edge E2 in the X direction. This is a trace made by a fact that the notches 101 and 102 have been provided on the alignment mark 100. That is, the edge E1 corresponds to a part connecting the tip of the notch 101 and the tip of the notch 102 to each other, and the edge E2 corresponds to the end part 121 extending in the X direction of the alignment mark 100. Among the remaining part 100A of the alignment mark 100, a region 131 including the edge E1 and the sections 1131 and 1161 shown in FIG. 2 has its length in the X direction extended as it is separated further from the edge E1. On the other hand, among the remaining part 100A of the alignment mark 100, a region 132 including the edge E2 and the sections 111 and 114 shown in FIG. 2 has a constant length in the X direction.

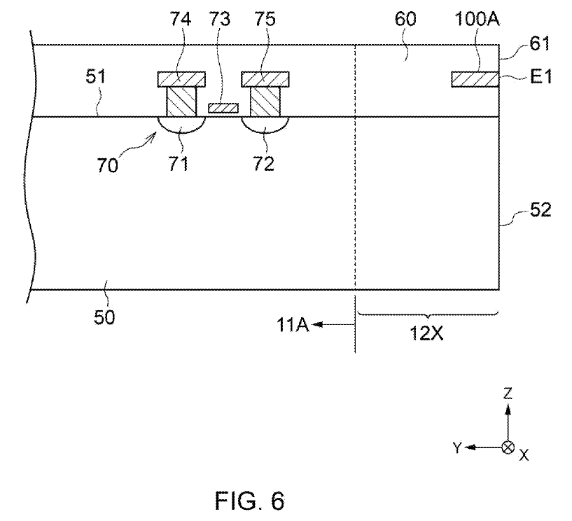

FIG. 6 is a schematic partial cross section showing a cross section of a diced semiconductor chip. As shown in FIG. 6, the circuit layer 60 is provided to cover a main surface 51 of the semiconductor substrate 50. A plurality of circuit elements such as transistors are formed on the main surface 51 of the semiconductor substrate 50. For example, a transistor 70 shown in FIG. 6 is constituted of source/drain regions 71 and 72 provided on the semiconductor substrate 50 and a gate electrode 73 covering a channel region positioned between the source/drain regions 71 and 72. The gate electrode 73 is positioned in the circuit layer 60. Wiring patterns 74 and 75 respectively connected to the source/drain regions 71 and 72 are present in the circuit layer 60. Circuit elements such as transistors are provided in the chip region 11A and any circuit element operated in actual use is not located in the scribe region 12X. The remaining part 100A of the alignment mark 100 remains in the scribe region 12X. The remaining part 100A of the alignment mark 100 is positioned in, for example, the same wiring layer as that of the wiring patterns 74 and 75. It is permissible that the remaining part 100A of the alignment mark 100 is not connected to circuit elements positioned in the circuit layer 60. It is also permissible that the remaining part 100A of the alignment mark 100 is in an electrically floating state.

As described above, in the present embodiment, since the notches 101 and 102 are provided on the alignment mark 100 located on the scribe regions 12X and 12Y, when the semiconductor wafer 10 is cut along the dicing line 13, a portion positioned on the chip region 11A side as viewed from the dicing line 13 remains on the chip region 11A side as the remaining part 100A, and a portion positioned on the chip region 11B side as viewed from the dicing line 13 remains on the chip region 11B side as the remaining part 100B. That is, since the alignment mark 100 is cut into two parts properly, poor appearance hardly occurs on diced semiconductor chips.

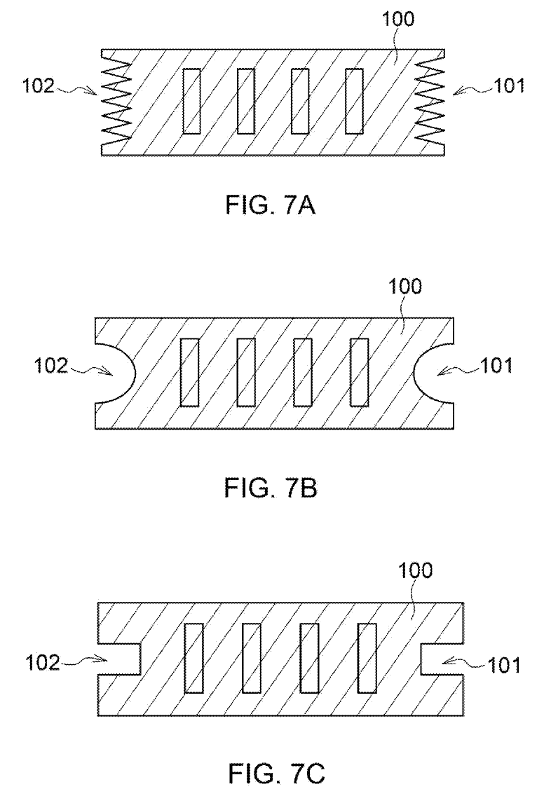

In the example shown in FIG. 2, while one notch is provided on each of both end parts of the alignment mark 100 on the X direction side, the number of notches is not limited thereto. As shown in FIG. 7A, a plurality of notches 101 and 102 may be respectively provided on both end parts of the alignment mark 100 on the X direction side. Further, the shape of the notches 101 and 102 does not need to be triangular and may be semicircular as shown in FIG. 7B, or may be rectangular as shown in FIG. 7C. In the case of the example shown in FIG. 7B, the tip of each of the notches 101 and 102 is rounded. In the case of the example shown in FIG. 7C, the tip of each of the notches 101 and 102 is flat.

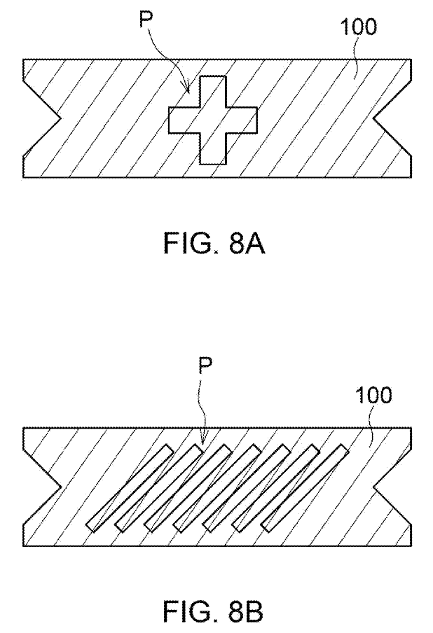

Further, in the example shown in FIG. 2, while a pattern in which the vias 32A or the via conductors 33 are arranged in the X direction is used as the pattern recognizing part P of the alignment mark 100, the pattern recognizing part P of the alignment mark 100 is not limited thereto. For example, as shown in FIG. 8A, a cross-shaped pattern may be used as the pattern recognizing part P of the alignment mark 100 and as shown in FIG. 8B, a plurality of patterns extending in an oblique direction may be used as the pattern recognizing part P of the alignment mark 100.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
first and second chip regions arranged in a first direction, each of the first and second chip regions including a plurality of circuit elements;
a scribe region arranged between the first and second chip regions in the first direction and extending in a second direction perpendicular to the first direction; and
a rectangle-shaped landing pattern having a notch at a substantially center portion in the first direction of each of two sides opposite to each other in the second direction.

2. The apparatus of claim 1, wherein the landing pattern includes a metal material.

3. The apparatus of claim 2, wherein the landing pattern is covered with an interlayer insulating film having a via hole overlapping the landing pattern.

4. The apparatus of claim 3, wherein the via hole is filled with a via conductor contacting the landing pattern.

5. The apparatus of claim 1, wherein the notch is triangular.

6. The apparatus of claim 1, wherein each of two sides of the landing pattern has a plurality of the notches.

7. The apparatus of claim 1, wherein the landing pattern is in an electrically floating state.

8. An apparatus comprising:
first and second chip regions arranged in a first direction, each of the first and second chip regions including a plurality of circuit elements;
a scribe region arranged between the first and second chip regions in the first direction and extending in a second direction perpendicular to the first direction; and
an alignment mark located on the scribe region,
wherein the alignment mark includes a metal pattern having a first end in one side of the second direction,
wherein the first end of the metal pattern includes a first section, a second section, and a third section located between the first and second sections in the first direction, and
wherein the third section of the first end of the metal pattern is located closer to another side of the second direction than the first and second sections such that at least a part of the first end of the metal pattern has a first notch.

9. The apparatus of claim 8,
wherein the metal pattern further has a second end in the another side of the second direction,
wherein the second end of the metal pattern includes a fourth section, a fifth section, and a sixth section located between the fourth and fifth sections in the first direction, and
wherein the sixth section of the second end of the metal pattern is located closer to the one side of the second direction than the fourth and fifth sections such that at least a part of the second end of the metal pattern has a second notch.

10. The apparatus of claim 9, wherein the first notch and the second notch are aligned in the second direction.

11. The apparatus of claim 8, wherein the first end of the metal pattern has a plurality of the first notches.

12. The apparatus of claim 8, wherein a tip of the first notch is sharp.

13. The apparatus of claim 8, wherein a tip of the first notch is rounded.

14. The apparatus of claim 8, wherein a tip of the first notch is flat.

15. The apparatus of claim 8, wherein a width of the first notch in the first direction is greater than half a width of the metal pattern.

16. The apparatus of claim 8, wherein a length of the first notch in the second direction is greater than a width of the first notch in the first direction.

17. An apparatus comprising:
a semiconductor substrate having a main surface in which a plurality of transistors are provided and a first side surface perpendicular to the main surface; and
a circuit layer covering the main surface of the semiconductor substrate and having a second side surface coplanar with the first side surface of the semiconductor substrate,
wherein the circuit layer has a plurality of wiring patterns including a first pattern,
wherein the first pattern has a first edge exposed from the second side surface of the circuit layer and a second edge embedded in the circuit layer and extending in parallel to the first edge, and
wherein the first edge is shorter than the second edge.

18. The apparatus of claim 17,
wherein the first pattern has a first portion including the first edge, and
wherein a length of the first portion of the first pattern in an extending direction of the first and second edges increases with distance from the second side surface of the circuit layer.

19. The apparatus of claim 18,
wherein the first pattern further has a second portion including the second edge, and
wherein a length of the second portion of the first pattern in the extending direction is substantially constant.

20. The apparatus of claim 17, wherein the first pattern is in an electrically floating state.
